(19) United States
(12) Patent Application Publication
(10) Pub. No.: US 2025/0210425 A1
(43) Pub. Date: Jun. 26, 2025

(54) METAL CORE SUBSTRATE AND METHOD OF PRODUCING THE METAL CORE SUBSTRATE

(71) Applicant: NITTO DENKO CORPORATION, Osaka (JP)

(72) Inventors: Takahiro IKEDA, Osaka (JP); Shusaku SHIBATA, Osaka (JP)

(73) Assignee: NITTO DENKO CORPORATION, Osaka (JP)

(21) Appl. No.: 18/985,948

(22) Filed: Dec. 18, 2024

(30) Foreign Application Priority Data
Dec. 25, 2023 (JP) 2023-218683

(51) Int. Cl. H01L 23/14; H01L 21/02; H01L 21/768; H01L 23/13; H01L 23/498

(52) U.S. Cl. CPC H01L 23/142; H01L 21/02118; H01L 21/76898; H01L 23/13; H01L 23/49827

(57) ABSTRACT

A metal core substrate includes a metal core layer, a first insulating layer, a first conductive pattern, a via, and an insulating member. The metal core layer has a through hole. The via is disposed in the through hole and connected to the first conductive pattern. The insulating member is disposed between an inner surface of the through hole and the via. The first insulating layer is made of polyimide. The insulating member is made of a material that differs from the first insulating layer.

### CROSS-REFERENCE TO RELATED APPLICATION

The present application claims priority from Japanese Patent Application No. 2023-218683 filed on Dec. 25, 2023, the content of which is hereby incorporated by reference into this application.

### TECHNICAL FIELD

The present invention relates to a metal core substrate and a method of producing the metal core substrate.

### BACKGROUND ART

Conventionally, a metal core printed wiring board includes a metal plate to be a core, a first insulating layer disposed on a one-side surface of the metal plate, a second insulating layer disposed on an other-side surface of the metal plate, a first wiring pattern disposed on the first insulating layer, and a second wiring pattern disposed on the second insulating layer. The first wiring pattern is electrically conducted to the second wiring pattern by a through hole plating penetrating the first insulating layer, the second insulating layer, and the metal plate (for example, see Patent document 1 below).

### CITATION LIST

### Patent Document

Patent Document 1: Japanese Unexamined Patent Publication No. 2009-200299

### SUMMARY OF THE INVENTION

### Problem to be Solved by the Invention

In the metal core printed wiring board described in Patent Document 1 described above, the first insulating layer and the second insulating layer are made of prepreg using glass cloth.

Therefore, the metal plate to be a core is constrained by the insulating layer containing glass cloth, and the flexibility of the metal core printed wiring board is low.

The present invention provides a metal core substrate capable of improving the flexibility, and a method of producing the metal core substrate.

### Means for Solving the Problem

The present invention [1] includes a metal core substrate including: a metal core layer having a through hole; a first insulating layer disposed on a one-side surface of the metal core layer in a thickness direction of the metal core layer; a second insulating layer disposed on an other-side surface of the metal core layer in the thickness direction; a first conductive pattern disposed on a one-side surface of the first insulating layer in the thickness direction; a second conductive pattern disposed on an other-side surface of the second insulating layer in the thickness direction; a via disposed in the through hole, the via extending in the thickness direction, the via whose one end portion in the thickness direction is connected to the first conductive pattern, the via whose other end portion in the thickness direction is connected to the second conductive pattern; and an insulating member disposed between an inner surface of the through hole and the via, wherein the first insulating layer is made of polyimide, and wherein the insulating member is made of a material different from the first insulating layer.

According to such a configuration, the first insulating layer disposed on the one-side surface of the metal core layer is made of polyimide.

Therefore, because of the flexibility of the polyimide, it is possible to improve the flexibility of the metal core substrate.

Further, the insulating member disposed in the through hole of the metal core layer is made of a material different from the material of the first insulating layer.

Therefore, it is possible to select a flexible polyimide as the material of the first insulating layer, and select, as the insulating member, a material different from that of the first insulating layer.

As a result, it is possible to ensure the degree of freedom in product design of the metal core substrate.

The present invention [2] includes the metal core substrate described in the above-described [1], wherein a dielectric breakdown voltage of the first insulating layer is higher than a dielectric breakdown voltage of the insulating member, and wherein the first insulating layer covers one end surface of the insulating member in the thickness direction.

According to such a configuration, the one end surface of the insulating member can be covered with the first insulating layer having a high dielectric breakdown voltage.

Therefore, it is possible to ensure the insulating property of the one end portion of the insulating member.

As a result, it is possible to reliably insulate the metal core layer in the connection portion between the one end portion of the via and the first conductive pattern.

The present invention [3] includes the metal core substrate described in the above-described [2], wherein between the inner surface of the through hole and the via, a thickness of the insulating member in a direction perpendicular to the thickness direction is larger than a thickness of the first insulating layer in the thickness direction.

According to such a configuration, it is possible to reliably insulate the metal core layer from the via while thinning the first insulating layer to reduce the thickness of the metal core substrate and ensuring the thickness of the insulating member.

The present invention [4] includes the metal core substrate described in any one of the above-described [1] or [3], wherein the metal core layer has a thickness of 100 μm or more.

The present invention [5] includes the metal core substrate described in any one of the above-described [1] or [4], wherein the thickness of the metal core layer is 5 times or more larger than the thickness of the first insulating layer in the thickness direction.

The present invention [6] includes the metal core substrate described in any one of the above-described [1] or [5], wherein a ratio of the thickness of the metal core layer is 0.2 or more with respect to a diameter of the through hole.

The present invention [7] includes the metal core substrate described in any one of the above-described [1] or [6], wherein the insulating member includes at least one type of resin selected from the group consisting of an epoxy resin, a silicone resin, and an acrylic resin.

The present invention [8] includes the metal core substrate described in any one of the above-described [1] or [7], wherein the first insulating layer is made of a cured product of a photosensitive polyimide.

The present invention [9] includes the metal core substrate described in any one of the above-described [1] or [8], wherein the second insulating layer is made of polyimide.

The present invention includes a method of producing the metal core substrate described in any one of the above-described [1] or [9], the method including: a through hole forming step of forming the through hole in the metal core layer, a covering step of covering the inner surface of the through hole with the insulating member, an insulating layer forming step of forming the first insulating layer, and a pattern forming step of forming the first conductive pattern and the via.

The present invention [1] includes the method of producing the metal core substrate described in the above-described [10], wherein in the covering step, an insulating resin containing no solvent is filled in the through hole, and the insulating member is made from the filled insulating resin.

According to such a method, as compared with the case of using an insulating resin containing a solvent, it is possible to reliably cover the inner surface of the through hole with the insulating member by suppressing the bubbles remaining in the insulating member.

Therefore, the metal core layer can reliably be insulated from the via.

The present invention [12] includes the method of producing the metal core substrate described in the above-described [10], wherein in the covering step, an insulating resin is coated to the inner surface of the through hole by electrodeposition coating.

According to such a method, it is possible to reliably cover the inner surface of the through hole with an [13] includes the method of producing the metal core substrate described in any one of the above-described [10] or [12], further including: a second through hole forming step of forming a through hole for passing the via therethrough in the insulating member.

The present invention includes the method of producing the metal core substrate

described in any one of the above-described [10] or [13], wherein the insulating layer forming step is carried out after the covering step to cover one end surface of the insulating member in the thickness direction with the first insulating layer.

The present invention [15] includes the method of producing the metal core substrate described in any one of the above-described [10] or [14], wherein a removal step of removing a portion of the insulating member protruding outside the through hole is carried out after the covering step and before the insulating layer forming step.

The present invention includes the method of producing the metal core substrate

described in any one of the above-described [10] or [15], wherein the via is formed at least on an inner surface of the insulating member.

### Effects of the Invention

According to the metal core substrate and the method of producing the metal core substrate of the present invention, it is possible to improve the flexibility of the metal core substrate.

### BRIEF DESCRIPTION OF THE DRAWINGS

FIG. 1 is a cross-sectional view of a metal core substrate as one embodiment of the present invention.

FIG. 2 is an enlarged view of the via shown in FIG. 1.

FIGS. 3A and 3D are views of steps showing a method of producing the metal core substrate shown in FIG. 1. FIG. 3A shows a step of forming a first through hole. FIG. 3B shows a covering step. FIG. 3C shows a removal step. FIG. 3D shows a step of forming an insulating layer.

Following FIG. 3D, FIGS. 4A to 4C are views of steps showing a method of producing the metal core substrate. FIG. 4A shows a step of forming a second through hole. FIG. 4B shows a step of forming a first conductor layer of a terminal, a wire, and a via in a pattern forming process. FIG. 4C shows a step of forming a second conductor layer of the terminal in the pattern forming process.

FIGS. 5A and 5B show variations of the through hole formed in the step of forming a first through hole. FIG. 5A shows the through hole made by wet etching. FIG. 5B shows the through hole made by laser machining.

FIGS. 6A and 6B show variations of the insulating member after the removal step. FIG. 6A shows a state in which both end surfaces of the insulating member are disposed in the through hole. FIG. 6B shows a state in which both end surfaces of the insulating member are disposed outside the through hole.

FIGS. 7A to 7C show variations of the via. FIG. 7A shows a case where the via is a through hole plating. FIG. 7B shows a case where the via is a through hole plating, and the resin is filled in the center of the via. FIG. 7C shows a case where the first conductive pattern and the second conductive pattern are formed separately from the via formed as a through hole plating.

### DESCRIPTION OF THE EMBODIMENT

### 1. Metal Core Substrate

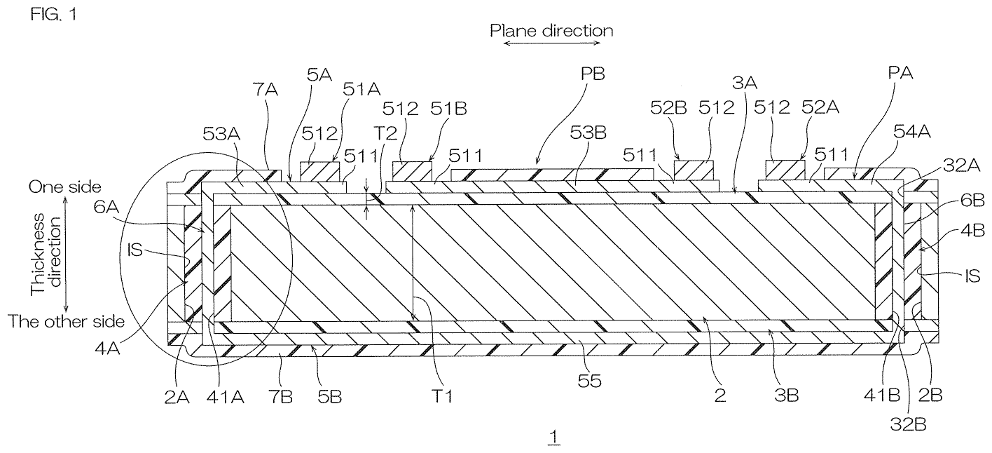

As shown in FIG. 1, a metal core substrate 1 includes a metal core layer 2, a first insulating layer 3A, a second insulating layer 3B, a plurality of insulating members 4A and 4B, a first conductive pattern 5A, a second conductive pattern 5B, a plurality of vias 6A and 6B, a first cover insulating layer 7A, and a second cover insulating layer 7B.
(1) Metal Core Layer

The metal core layer 2 is a core made of metal. The metal core layer 2 is disposed between the first insulating layer 3A and the second insulating layer 3B in the thickness of the metal core layer 2. In the present embodiment, examples of the material of the metal core layer 2 include, for example, a stainless steel and a copper alloy. The metal core layer 2 is preferably made of a copper alloy. The metal core layer 2 has a plurality of through holes 2A and 2B.

A thickness T1 of the metal core layer 2 is, for example, 100 μm or more, preferably 120 μm or more. When the thickness T1 of the metal core layer 2 is the above-described lower limit or more, it is particularly difficult to cover an inner surface IS of each of the through holes 2A and 2B with a resin.

The upper limit of the thickness T1 of the metal core layer 2 is not limited. The thickness T1 of the metal core layer 2 is, for example, 500 μm or less, preferably 250 μm or less. The thickness T1 of the metal core layer 2 may be 100 μm to 500 μm, or 120 μm to 250 μm.

The thickness T1 of the metal core layer 2 is, for example, 5 times or more, preferably 10 times or more larger than a thickness T2 of the first insulating layer 3A in the thickness direction of the metal core layer 2.

When the thickness T1 of the metal core layer 2 is the above-described lower limit or more with respect to the thickness T2 of the first insulating layer 3A, it is particularly difficult to cover the inner surface IS of each of the through holes 2A and 2B with the same resin as that of the first insulating layer 3A.

The thickness T1 of the metal core layer 2 is, for example, 100 times or less larger than the thickness T2 of the first insulating layer 3A. The thickness T1 of the metal core layer 2 may be 5 to 100 times or 10 to 100 times larger than the thickness T2 of the first insulating layer 3A.

With respect to the diameter of each of the through holes 2A and 2B, the ratio of the thickness T1 of the metal core layer 2 is, for example, 0.2 or more, preferably 0.5 or more.

When the thickness T1 of the metal core layer 2 is the above-described lower limit or more with respect to the diameter of each of the through holes 2A and 2B, it is particularly difficult to cover the inner surface IS of each of the through holes 2A and 2B with a resin.

With respect to the diameter of each of the through holes 2A and 2B, the ratio of the thickness T1 of the metal core layer 2 is, for example, 10 or less.
(2) First Insulating Layer

The first insulating layer 3A is disposed on one side of the metal core layer 2 in the thickness direction. The first insulating layer 3A is disposed on a one-side surface of the metal core layer 2 in the thickness direction. The first insulating layer 3A is in contact with the one-side surface of the metal core layer 2. The first insulating layer 3A is disposed between the metal core layer 2 and the first conductive pattern 5A in the thickness direction. The first insulating layer 3A insulates the metal core layer 2 from the first conductive pattern 5A. The first insulating layer 3A is made of polyimide. The first insulating layer 3A is preferably made of a cured product of photosensitive polyimide.

The dielectric breakdown voltage of the first insulating layer 3A is higher than that of the insulating members 4A and 4B. The dielectric breakdown voltage of the first insulating layer 3A is, for example, 50 kV/mm to 600 kV/mm, preferably 100 kV/mm to 500 kV/mm.
(3) Second Insulating Layer

The second insulating layer 3B is disposed on the other side of the metal core layer 2 in the thickness direction. The second insulating layer 3B is disposed on the other-side surface of the metal core layer 2 in the thickness direction. The second insulating layer 3B is in contact with the other-side surface of the metal core layer 2. The second insulating layer 3B is disposed between the metal core layer 2 and the second conductive pattern 5B in the thickness direction. The second insulating layer 3B insulates the metal core layer 2 from the second conductive pattern 5B. The second insulating layer 3B is made of the same material as that of the first insulating layer 3A. That is, the dielectric breakdown voltage of the second insulating layer 3B is the same as that of the first insulating layer 3A, and lower than those of the insulating members 4A and 4B.
(4) Insulating Member

The insulating member 4A is disposed in the through hole 2A. The insulating member 4A is disposed between the first insulating layer 3A and the second insulating layer 3B in the thickness direction. The insulating member 4A extends in the thickness direction. One end portion of the insulating member 4A in the thickness is in contact with the first insulating layer 3A. The other end portion of the insulating member 4A in the thickness is in contact with the second insulating layer 3B. One end surface of the insulating member 4A in the thickness direction may be flush with the one-side surface of the metal core layer 2 in the thickness direction. The other end surface of the insulating member 4A in the thickness direction may be flush with the other-side surface of the metal core layer 2 in the thickness direction. The insulating member 4A is disposed between the inner surface IS of the through hole 2A and the via 6A in a plane direction perpendicular to the thickness direction. The insulating member 4A insulates the metal core layer 2 from the via 6A. The insulating member 4A has a through hole 41A through which the via 6A passes.

The insulating member 4A is made of a material that differs from that of the first insulating layer 3A. Specifically, the insulating member 4A includes at least one type of resin selected from the group consisting of an epoxy resin, a silicone resin, and an acrylic resin. As the resin of the insulating member 4A, an epoxy resin and a silicone resin are preferably used.

The insulating member 4A may further include an inorganic filler. The insulating member 4A preferably contains an inorganic filler. In other words, the insulating member 4A is preferably made of a composite material of a resin (matrix resin) and an inorganic filler.

The dielectric breakdown voltage of the insulating member 4A is, for example, 5 kV/mm to 200 kV/mm, preferably 50 kV/mm to 150 kV/mm.

The insulating member 4B is disposed in the through hole 2B. The insulating member 4B is disposed between the first insulating layer 3A and the second insulating layer 3B in the thickness direction. The insulating member 4B extends in the thickness direction. One end portion of the insulating member 4B in the thickness is in contact with the first insulating layer 3A. The other end portion of the insulating member 4B in the thickness is in contact with the second insulating layer 3B. The one end surface of the insulating member 4B in the thickness direction may be flush with the one-side surface of the metal core layer 2 in the thickness direction. The other end surface of the insulating member 4B in the thickness direction may be flush with the other-side surface of the metal core layer 2 in the thickness direction. The insulating member 4B is disposed between the inner surface IS of the through hole 2B and the via 6B in the plane direction perpendicular to the thickness direction. The insulating member 4B insulates the metal core layer 2 from the via 6B. The insulating member 4B has a through hole 41B through which the via 6B passes. The insulating member 4B is made of the same material as that of the insulating member 4A. That is, the dielectric breakdown voltage of the insulating member 4B is the same as that of the insulating member 4A.
(5) First Conductive Pattern

The first conductive pattern 5A is disposed at one side of the metal core layer 2 in the thickness direction. The first conductive pattern 5A is disposed on the one-side surface of the first insulating layer 3A in the thickness direction. The first conductive pattern 5A is made of metal. Examples of the metal include copper. The shape of the first conductive pattern 5A is not limited.

For example, the first conductive pattern 5A has a pattern PA and a pattern PB.

The pattern PA consists of a plurality of terminals 51A and 52A and a plurality of wires 53A and 54A.

The terminal 51A is spaced away from the terminal 52A in the plane direction. Each of the terminals 51A and 52A has a first conductor layer 511 and a second conductor layer 512. The first conductor layer 511 is disposed on the first insulating layer 3A in the thickness direction. The secondary conductor layer 512 is disposed on the first conductor layer 511 in the thickness direction.

The wire 53A electrically connects the terminal 51A and the via 6A. One end portion of the wire 53A is connected to the first conductor layer 511 of the terminal 51A. The other end portion of the wire 53A is connected to the via 6A.

The wire 54A electrically connects the terminal 52A and the via 6B. One end portion of the wire 54A is connected to the first conductor layer 511 of the terminal 52A. The other end portion of the wire 54A is connected to the via 6B.

The pattern PB consists of a plurality of terminals 51B and 52B and the wire 53B. The pattern PB is spaced away from the pattern PA. At least a portion of the pattern PB is disposed between the terminal 51A and the terminal 52A in the plane direction.

The terminal 51B is spaced away from the terminal 52B in the plane direction. Each of the terminals 51B and 52B has a first conductor layer 511 and a second conductor layer 512 in the same manner as each of the terminals 51A and 52A does.

The wire 53B electrically connects the terminal 51B and the terminal 52B. One end portion of the wire 53B is connected to the first conductor layer 511 of the terminal 51B. The other end portion of the wire 53B is connected to the first conductor layer 511 of the terminal 52B.
(6) Second Conductive Pattern

The second conductive pattern 5B is disposed on the other side of the metal core layer 2 in the thickness direction. The second conductive pattern 5B is disposed on the other-side surface of the second insulating layer 3B in the thickness direction. The second conductive pattern 5B is made of the same metal as that of the first conductive pattern 5A. The shape of the second conductive pattern 5B is not limited.

For example, the second conductive pattern 5B has a wire 55.

The wire 55 electrically connects the via 6A and the via 6B. One end portion of the wire 55 is connected to the via 6A. The other end portion of the wire 55 is connected to the via 6B.
(7) Via

The via 6A is disposed in the through hole 2A of the metal core layer 2. The via 6A is disposed in the through hole 41A of the insulating member 4A. The via 6A extends in the thickness direction. One end portion of the via 6A in the thickness is connected to the wire 53A of the first conductive pattern 5A. The other end portion of the via 6A in the thickness is connected to the wire 55 of the second conductive pattern 5B. The via 6A is made of the same metal as that of the first conductive pattern 5A.

The via 6B is disposed in the through hole 2B of the metal core layer 2. The via 6B is disposed in the through hole 41B of the insulating member 4B. The via 6B extends in the thickness direction. One end portion of the via 6B in the thickness direction is connected to the wire 54A of the first conductive pattern 5A. The other end portion of the via 6B in the thickness direction is connected to the wire 55 of the second conductive pattern 5B. The via 6B is made of the same metal as that of the first conductive pattern 5A.

### 2. Details of Structure Around Via

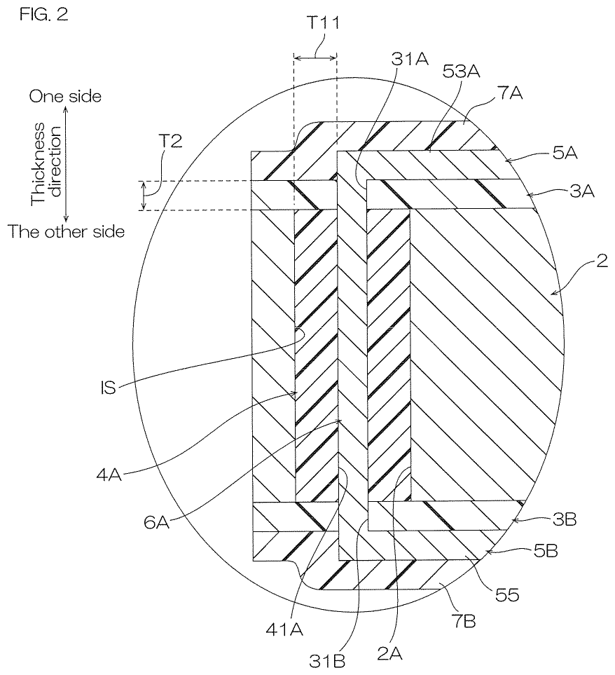

Next, with reference to FIG. 2, the details of the structure around the via are described.

As shown in FIG. 2, the first insulating layer 3A covers one end surface of the insulating member 4A in the thickness direction. In this manner, it is possible to protect the one end portion of the insulating member 4A by the first insulating layer 3A having a lower elastic modulus than that of the insulating member 4A, and thus it is possible to suppress a crack in the one end portion of the insulating member 4A.

The first insulating layer 3A has a through hole 31A and a through hole 32A (see FIG. 1). One end portion of the via 6A in the thickness direction passes through the through hole 31A, and is connected to the wire 53A of the first conductive pattern 5A. One end portion of the via 6B in the thickness direction passes through the through hole 32A, and is connected to the wire 54A of the first conductive pattern 5A.

Between the inner surface IS of the through hole 2A and the via 6A, the thickness T11 of the insulating member 4A in the plane direction is larger than the thickness T2 of the first insulating layer 3A in the thickness direction. Therefore, even when the dielectric breakdown voltage of the insulating member 4A is lower than that of the first insulating layer 3A, the metal core layer 2 can be insulated from the via 6A.

The thickness T2 of the first insulating layer 3A is, for example, 5 μm or more, preferably 10 μm or more. When the thickness T2 of the first insulating layer 3A is the above-described lower limit or more, it is possible to reliably insulate the metal core layer 2 from the first conductive pattern 5A.

The thickness T2 of the first insulating layer 3A is, for example, 20 μm or less, preferably 15 μm or less. When the thickness T2 of the first insulating layer 3A is the above-described upper limit or less, it is possible to reduce the thickness of the metal core substrate 1.

The thickness T2 of the first insulating layer 3A may be 5 μm to 20 μm, or 10 μm to 15μm.

The thickness T11 of the insulating member 4A is, for example, 15 μm or more, preferably 25 μm or more. When the thickness T11 of the insulating member 4A is the above-described lower limit or more, it is possible to reliably insulate the metal core layer 2 from the via 6A.

The thickness T11 of the insulating member 4A is, for example, 100 μm or less, preferably 85 μm or less. When the thickness T11 of the insulating member 4A is the above-described upper limit or less, it is possible to reduce the diameter of the via 6A with the miniaturization of the metal core substrate 1.

The thickness T11 of the insulating member 4A may be 15 μm to 100 μm, or 25 μm to 85 μm.

The second insulating layers 3B covers the other end surface of the insulating member 4A in the thickness direction. In this manner, it is possible to protect the other end portion of the insulating member 4A by the second insulating layer 3B having a lower elastic modulus than that of the insulating member 4A, and it is possible to suppress a crack in the other end portion of the insulating member 4A.

The second insulating layer 3B has a through hole 31B and a through hole 32B (see FIG. 1). The other end portion of the via 6A in the thickness direction passes through the through hole 31B, and is connected to the wire 55 of the second conductive pattern 5B. The other end portion of the via 6B in the thickness direction passes through the through hole 32B, and is connected to the wire 55 of the second conductive pattern 5B. The thickness of the second insulating layer 3B is the same as the thickness T2 of the first insulating layer 3A.

### 3. Method of Producing Metal Core Substrate

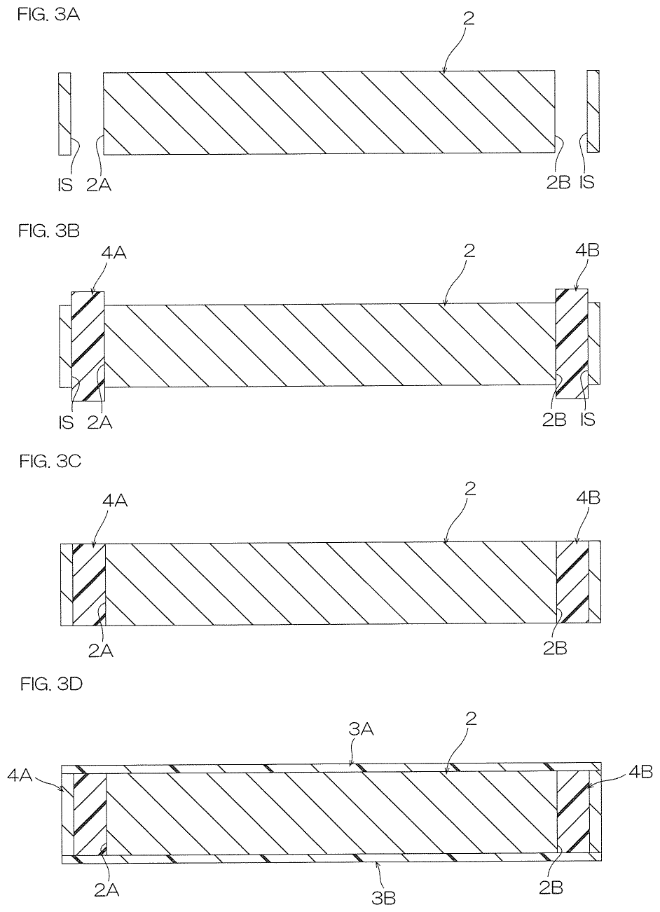

Next, referring to FIGS. 3A to 7C, a method of producing the metal core substrate 1 is described.

A method of producing the metal core substrate 1 includes a step of forming a first through hole as an example of a through hole forming step (see FIG. 3A), a covering step (see FIG. 3B), a removal step (see FIG. 3C), a step of forming an insulating layer (see FIG. 3D), a step of forming a second through hole (see FIG. 4A), a step of forming a pattern (see FIGS. 4B and 4C), and a step of forming a cover insulating layer (see FIG. 1).

As shown in FIG. 3A, in the step of forming a first through hole, through holes 2A and 2B are formed in the metal core layer 2. The through holes 2A and 2B are formed, for example, using a drill. When a drill is used to form the through holes 2A and 2B, the inner surface IS of each of the through holes 2A and 2B extends straight in the thickness direction.

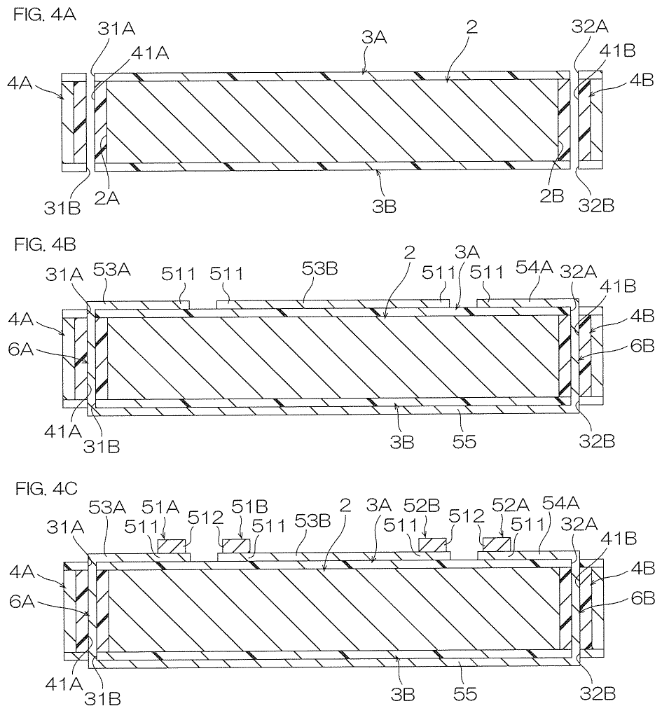

The method of forming the through holes 2A and 2B is not limited. For example, the through holes 2A and 2B may be formed by wet etching. When the through holes 2A and 2B are formed by wet etching, as shown in FIG. 5A, the central portion of the inner surface IS of each of the through holes 2A and 2B in the thickness direction may be recessed.

Further, the through holes 2A and 2B may be formed by laser processing. When the through holes 2A and 2B are formed from one side in the thickness direction by laser processing, as shown in FIG. 5B, the inner surface IS of each of the through holes 2A and 2B may have a taper which tapers from one side in the thickness direction toward the other side in the thickness direction.
(2) Covering Process

Next, as shown in FIG. 3B, in the covering step, the inner surface IS of the through hole 2A is covered with the insulating member 4A while the inner surface IS of the through hole 2B is covered with the insulating member 4B. In the covering step, for example, an insulating resin containing no solvent is filled in each of the through holes 2A and 2B in a reduced pressure environment. The insulating member 4A is made of the insulating resin filled in the through hole 2A. The insulating member 4B is made of the insulating resin filled in the through hole 2B.

Examples of the insulating resin containing no solvent include a solvent-free type epoxy resin, a solvent-free type silicone resin, and a solvent-free type acrylic resin. As the insulating resin containing no solvent, a solvent-free type silicone resin and a solvent-free type epoxy resin are preferably used. The insulating resin may contain an inorganic filler. Preferably, the insulating resin contains an inorganic filler.

When a solvent-free type silicone resin or a solvent-free type epoxy resin is used as an insulating resin containing no solvent, the insulating resin containing no solvent is filled in each of the through holes 2A and 2B and cured in the covering step. That is, each of the insulating members 4A and 4B is a cured product of the insulating resin containing no solvent.
(3) Removal Process

Next, as shown in FIG. 3C, after the covering step and prior to the step of forming an insulating layer, if necessary, a removal step is carried out. In the removal step, a portion of the insulating member 4A protruding to the outside of the through hole 2A and a portion of the insulating member 4B protruding to the outside of the through hole 2B are removed.

The method of removing the portion of each of the insulating members 4A and 4B is not limited. To remove the portion of each of the insulating members 4A and 4B, for example, the portion of each of the insulating members 4A and 4B is scraped off.

After the removal step, the one end surfaces of the insulating members 4A and 4B in the thickness direction may not be flush with the one-side surface of the metal core layer 2 in the thickness direction. The other end surfaces of the insulating members 4A and 4B in the thickness direction may not be flush with the other-side surface of the metal core layer 2 in the thickness direction.

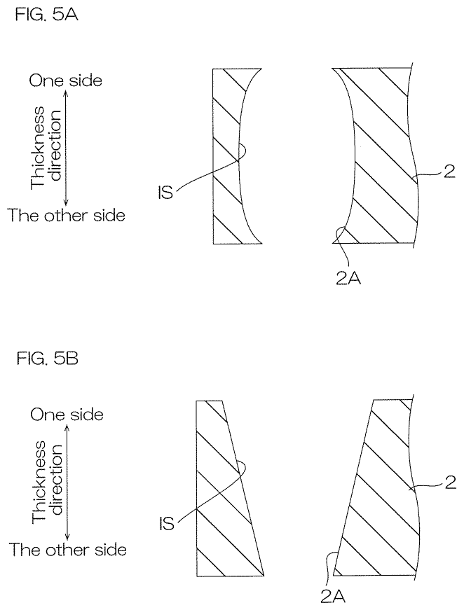

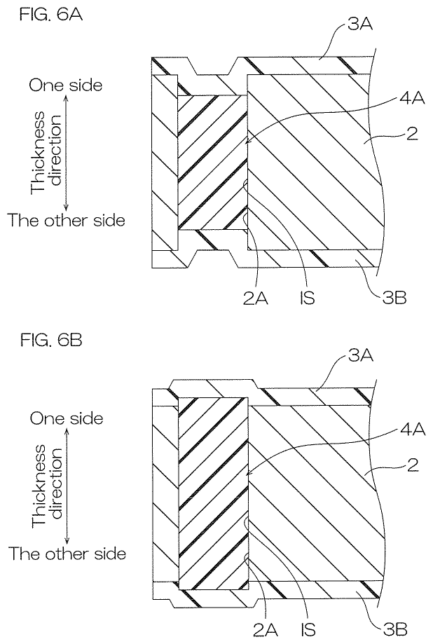

For example, as shown in FIG. 6A, the end surface of the insulating member 4A may be disposed in the through hole 2A. In detail, the one end surface of the insulating member 4A in the thickness direction may be disposed at the other side as compared with the one-side surface of the metal core layer 2 in the thickness direction. Furthermore, the other end surface of the insulating member 4A in the thickness direction may be disposed at one side as compared with the other-side surface of the metal core layer 2 in the thickness direction. In the same manner, the end surface of the insulating member 4B may be disposed in the through hole 2B.

Alternatively, as shown in FIG. 6B, the end surface of the insulating member 4A may be disposed outside the through hole 2A. In detail, the one end surface of the insulating member 4A in the thickness direction may be disposed at one side as compared with the one-side surface of the metal core layer 2 in the thickness direction. The other end surface of the insulating member 4A in the thickness direction may be disposed at the other side as compared with the other-side surface of the metal core layer 2 in the thickness direction. In the same manner, the end surface of the insulating member 4B may be disposed outside the through hole 2B.
(4) Step of Forming Insulating Layer

Next, as shown in FIG. 3D, after the covering step, the step of forming an insulating layer is carried out.

In the step of forming an insulating layer, a first insulating layer 3A and a second insulating layer 3B are formed. In the step of forming an insulating layer, the one end surface of each of the insulating members 4A and 4B in the thickness direction is covered with the first insulating layer 3A, and the other end surface of each of the insulating members 4A and 4B in the thickness direction is covered with the second insulating layer 3B.

In detail, to form the first insulating layer 3A and the second insulating layer 3B, first, a solution (varnish) of a photosensitive resin is applied onto the one-side surface of the metal core layer 2 and the one end surface of each of the insulating members 4A and 4B, and the photosensitive resin varnish is applied onto the other-side surface of the metal core layer 2 and the other end surface of each of the insulating members 4A and 4B.

Next, the applied varnish is dried to form a coating film of the photosensitive resin. Next, the coating film of the photosensitive resin is exposed to light and developed. In this manner, the first insulating layer 3A and the second insulating layer 3B are formed.
(5) Step of Forming Second Through Hole

Next, as shown in FIG. 4A, in the step of forming a second through hole, a through hole 41A for passing the via 6A therethrough (see FIG. 1) is formed in the insulating member 4A, and a through hole 41B for passing the via 6B therethrough (see FIG. 1) is formed in the insulating member 4B. The through holes 41A and 41B are formed, for example, by laser processing.

When the through hole 41A is formed, a through hole 31A of the first insulating layer 3A and a through hole 31B of the second insulating layer 3B are also formed together with the through hole 41A. Furthermore, when the through hole 41B is formed, a through hole 32A of the first insulating layer 3A and a through hole 32B of the second insulating layer 3B are also formed together with the through hole 41B.
(6) Step of Forming Pattern

Next, as shown in FIGS. 4B and 4C, in the step of forming a pattern, a first conductive pattern 5A, a second conductive pattern 5B, and vias 6A and 6B are formed.

In detail, as shown in FIG. 4B, a first conductor layer 511 of each of the terminals 51A, 52A,51B, and 52B; wires 53A, 54A, and 53B; a wire 55; and vias 6A and 6B are formed.

First, a seed layer is formed on the surface of the first insulating layer 3A, the surface of the second insulating layer 3B, the inner surfaces of the through holes 31A, 41A, and 31B, and the inner surfaces of the through holes 32A, 41B, and 32B. The seed layer is formed, for example, by sputtering. Examples of the material of the seed layer include, for example, chromium, copper, nickel, titanium, and the alloys thereof. The seed layer may be one layer made of one type of metal, and may be a plurality of layers (e.g., a chromium layer and a copper layer) made of different types of metals from each other.

Next, a first plating resist is attached onto the first insulating layer 3A, and a second plating resist is attached onto the second insulating layer 3B.

Next, the first plating resist is exposed to light in a state in which the first conductor layer 511 of each of the terminals 51A, 52A, 51B, and 52B and the portions where the wires 53A, 54A, and 53B are formed are shielded from light. Furthermore, the second plating resist is exposed to light in a state in which the portion where the wire 55 is formed is shielded from light.

Next, the first plating resist and the second plating resist are developed. Then, the shielded portion of the first plating resist is removed, and the seed layer is exposed in the portions where the respective first conductor layer 511 of each of the terminals 51A, 52A, 51B, and 52B and the wires 53A, 54A, and 53B are formed. Furthermore, the shielded portion of the second plating resist is removed, and the seed layer is exposed in the portion where the wire 55 is formed. On the other hand, the exposed portion of each of the first plating resist and the second plating resist remains.

Next, the first conductor layer 511 of each of the terminals 51A, 52A, 51B, and 52B, the wires 53A, 54A, and 53B, and the wire 55 are formed on the seed layer by electroplating.

At the time, the plating solution also enters the through holes 31A, 41A, and 31B, and the through holes 32A, 41B, and 32B. Therefore, the via 6A is formed in the through holes 31A, 41A, and 31B, and the via 6B is formed in the through holes 32A, 41B, and 32B. The via 6A is formed at least on the inner surfaces of the through holes 31A, 41A, and 31B. That is, the via 6A is formed at least on the inner surface of the insulating member 4A. In the present embodiment, the via 6A is filled in the through holes 31A, 41A, and 31B. Further, the via 6B is formed at least on the inner surfaces of the through holes 32A, 41B, and 32B. In the present embodiment, the via 6B is filled in the through holes 32A, 41B, and 32B.

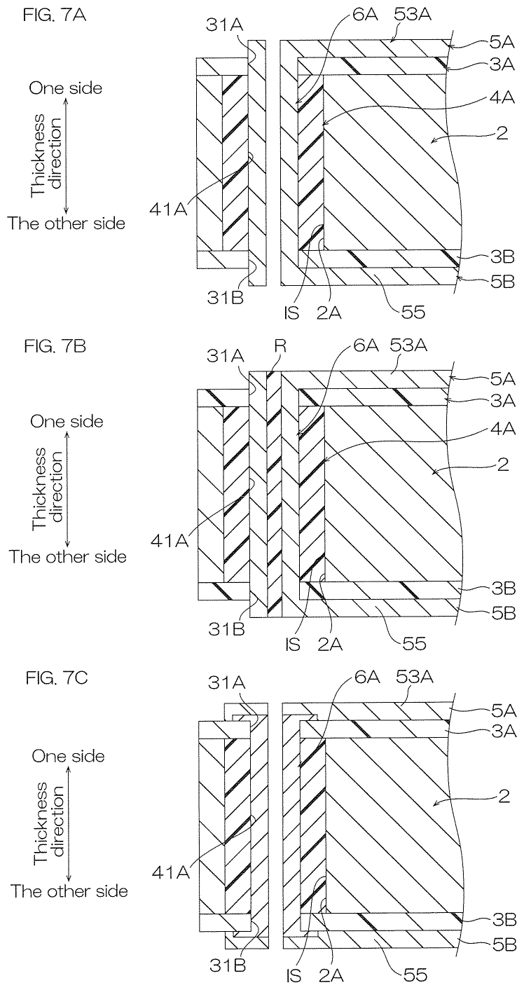

As shown in FIG. 7A, the via 6A may not be filled in the through holes 31A, 41A, and 31B. Furthermore, the via 6B may not be filled in the through holes 32A, 41B, and 32B. The vias 6A and 6B may be through hole platings.

Furthermore, as shown in FIG. 7B, when the vias 6A and 6B are through hole platings, the centers of the vias 6A and 6B may be filled with a resin R.

Furthermore, as shown in FIG. 7C, in the step of forming a pattern, after the vias 6A and 6B are formed as through hole platings, the first conductive pattern 5A and the second conductive pattern 5B may be formed by electrolytic plating.

After the electrolytic plating is completed, the first plating resist and the second plating resist are peeled off.

Next, as shown in the FIG. 4C, a second conductor layer 512 is formed on the first conductor layers 511 of each of the terminals 51A, 52A, 51B, and 52B.

In detail, a third plating resist is attached onto the first insulating layer 3A; the first conductor layer 511 of each of the terminals 51A, 52A, 51B, and 52B; and the wires 53A, 54A, and 53B. A fourth plating resist is attached on the second insulating layer 3B and the wire 55.

Next, the third plating resist is exposed to light in a state in which the portion where the second conductor layer 512 of each of the terminals 51A, 52A, 51B, and 52B is formed is shielded. Furthermore, the entire fourth plating resist is exposed to light.

Next, the third plating resist and the fourth plating resist are developed. Then, the shielded portion of the third plating resist is removed, and then the first conductor layer 511 is exposed in the portion where the second conductor layer 512 of each of the terminals 51A, 52A, 51B, and 52B is formed. On the other hand, the exposed portion of the third plating resist and the entire fourth plating resist remain.

Next, a second conductor layer 512 is formed on the first conductor layer 511 by electrolytic plating.

After the electrolytic plating is completed, the third plating resist and the fourth plating resist are peeled off. Thereafter, the seed layer exposed by the peeling of the third plating resist and the fourth plating resist is removed by etching.
(7) Step of Forming Cover Insulating Layer

Next, as shown in FIG. 1, in the step of forming a cover insulating layer, a first cover insulating layer 7A is formed on the first insulating layer 3A and the first conductive pattern 5A in the same manner as the formation of the first insulating layer 3A. Furthermore, a second cover insulating layer 7B is formed on the second insulating layer 3B and the second conductive pattern 5B in the same manner as the formation of the second insulating layer 3B.

As described above, the metal core substrate 1 is completed.

### 3. Operations and Effects

(1) According to the metal core substrate 1, as shown in FIG. 1, the first insulating layer 3A disposed on the one-side surface of the metal core layer 2 and the second insulating layer 3B disposed on the other-side surface of the metal core layer 2 are made of polyimide.

Therefore, the flexibility of the polyimide can improve the flexibility of the metal core substrate 1.

Furthermore, the insulating member 4A disposed in the through hole 2A of the metal core layer 2 and the insulating member 4B disposed in the through hole 2B of the metal core layer 2 are made of a material different from those of the first insulating layer 3A and the second insulating layer 3B.

Therefore, it is possible to select a flexible polyimide as the material of the first insulating layer 3A and the second insulating layer 3B, and then select a material different from that of the first insulating layer 3A and the second insulating layer 3B as the material of the insulating members 4A and 4B.

As a result, it is possible to ensure the degree of freedom in product design of the metal core substrate 1.
(2) According to the metal core substrate 1, as shown in FIG. 1, the one end surfaces of the insulating members 4A and 4B are covered with the first insulating layer 3A, and the other end surfaces of the insulating members 4A and 4B are covered with the second insulating layer 3B. The first insulating layer 3A and the second insulating layer 3B have a higher dielectric breakdown voltage than those of the insulating members 4A and 4B.

In this manner, it is possible to cover the one end surface of each of the insulating members 4A and 4B with the first insulating layer 3A having a high dielectric breakdown voltage, and cover the other end surface of each of the insulating members 4A and 4B with the second insulating layer 3B having a high dielectric breakdown voltage.

Therefore, it is possible to ensure the insulating properties of the one end portion and the other end portion of each of the insulating members 4A and 4B.

Consequently, it is possible to reliably insulate the metal core layer 2 in the connection portion between the one end portion of each of the vias 6A and 6B and the first conductive pattern 5A, and the connection portion between the other end portion of each of the vias 6A and 6B and the second conductive pattern 5B.
(3) According to the metal core substrate 1, as shown in FIG. 2, the thickness T11 of the insulating member 4A is larger than the thickness T2 of the first insulating layer 3A.

Therefore, it is possible to reliably insulate the metal core layer 2 from the via 6A while thinning the first insulating layer 3A to reduce the thickness of the metal core substrate 1 and ensuring the thickness of the insulating member 4A.
(4) According to the method of producing the metal core substrate 1, as shown in FIG. 3B, in the covering step, an insulating resin containing no solvent is filled in the through hole 2A, and the insulating member 4A is made from the filled insulating resin.

In this manner, as compared with when an insulating resin containing a solvent is used, it is possible to reliably cover the inner surface of the through hole 2A with an insulating member 4A by suppressing that air bubbles remain in the insulating member 4A.

Therefore, the metal-core-layer 2 can be reliably insulated from the via 6A.

### 4. Variations

Next, variations are described. In the variations, the same members as in the above-described embodiment are given the same reference numerals, and the descriptions thereof are omitted.
(1) In the covering step, the insulating resin may be coated to the inner surface IS of each of the through holes 2A and 2B by electrodeposition coating.

The electrodeposition coating makes it possible to reliably cover the inner surface IS of each of the through holes 2A and 2B with an insulating resin. Therefore, the metal core layer 2 can reliably be insulated from the vias 6A and 6B.
(2) In the embodiment described above, the vias 6A and 6B are formed by electrolytic plating in the step of forming a pattern (see FIG. 4B). However, the method of forming the vias 6A and 6B is not limited to electrolytic plating. The vias 6A and 6B may be formed from a conductive material such as a metallic ink, a conductive paste, a solder, and the like. When the vias 6A and 6B are formed from these conductive materials, a seed layer may not be formed.
(3) In the variations (1) and (2), the same operations and effects as those of the above-described embodiment can be obtained.

While the illustrative embodiments of the present invention are provided in the above description, such is for illustrative purpose only and it is not to be construed as limiting in any manner. Modification and variation of the present invention that will be obvious to those skilled in the art is to be covered by the following claims.

### INDUSTRIAL APPLICABILITY

The metal core substrate of the present invention can be used for the connection of electronic components.

### DESCRIPTION OF REFERENCE NUMERALS

1 Metal core substrate
2 Metal core layer
2A Through hole of the metal core layer
3A First insulating layer
3B Second insulating layer
4A Insulating member
41A Through hole of the insulating member
5A First conductive pattern
5B Second conductive pattern
6A Via
6B Via
IS Inner surface of the through hole

1. A metal core substrate comprising:
a metal core layer having a through hole;
a first insulating layer disposed on a one-side surface of the metal core layer in a thickness direction of the metal core layer;
a second insulating layer disposed on an other-side surface of the metal core layer in the thickness direction;
a first conductive pattern disposed on a one-side surface of the first insulating layer in the thickness direction;
a second conductive pattern disposed on an other-side surface of the second insulating layer in the thickness direction;
a via disposed in the through hole, the via extending in the thickness direction, the via whose one end portion in the thickness direction is connected to the first conductive pattern, the via whose other end portion in the thickness direction is connected to the second conductive pattern; and
an insulating member disposed between an inner surface of the through hole and the via, wherein the first insulating layer is made of polyimide, and
wherein the insulating member is made of a material different from the first insulating layer.

2. The metal core substrate according to claim 1,
wherein a dielectric breakdown voltage of the first insulating layer is higher than a dielectric breakdown voltage of the insulating member, and
wherein the first insulating layer covers one end surface of the insulating member in the thickness direction.

3. The metal core substrate according to claim 2,
wherein between the inner surface of the through hole and the via, a thickness of the insulating member in a direction perpendicular to the thickness direction is larger than a thickness of the first insulating layer in the thickness direction.

4. The metal core substrate according to claim 1,
wherein the metal core layer has a thickness of 100 μm or more.

5. The metal core substrate according to claim 1,
wherein the thickness of the metal core layer is 5 times or more larger than the thickness of the first insulating layer in the thickness direction.

6. The metal core substrate according to claim 1,
wherein a ratio of the thickness of the metal core layer is 0.2 or more with respect to a diameter of the through hole.

7. The metal core substrate according to claim 1,
wherein the insulating member includes at least one type of resin selected from the group consisting of an epoxy resin, a silicone resin, and an acrylic resin.

8. The metal core substrate according to claim 1,
wherein the first insulating layer is made of a cured product of a photosensitive polyimide.

9. The metal core substrate according to claim 1,
wherein the second insulating layer is made of polyimide.

10. A method of producing the metal core substrate according to claim 1, the method comprising:
a through hole forming step of forming the through hole in the metal core layer,
a covering step of covering the inner surface of the through hole with the insulating member,
an insulating layer forming step of forming the first insulating layer, and
a pattern forming step of forming the first conductive pattern and the via.

11. The method according to claim 10,
wherein in the covering step, an insulating resin containing no solvent is filled in the through hole, and the insulating member is made from the filled insulating resin.

12. The method according to claim 10,
wherein in the covering step, an insulating resin is coated to the inner surface of the through hole by electrodeposition coating.

13. The method according to claim 10, further comprising:
a second through hole forming step of forming a through hole for passing the via therethrough in the insulating member.

14. The method according to claim 10,
wherein the insulating layer forming step is carried out after the covering step to cover one end surface of the insulating member in the thickness direction with the first insulating layer.

15. The method according to claim 10,
wherein a removal step of removing a portion of the insulating member protruding outside the through hole is carried out after the covering step and before the insulating layer forming step.

16. The method according to claim 10,
wherein the via is formed at least on an inner surface of the insulating member.
